(19) United States
(12) Patent Application Publication
(10) Pub. No.: US 2012/0082322 A1
(43) Pub. Date: Apr. 5, 2012

(54) SOUND SCENE MANIPULATION

(75) Inventors: Toon van Waterschoot, Leuven (BE); Wouter Joos Tirry, Wijgmaal (BE); Marc Moonen, Leuven (BE)

(73) Assignee: NXP B.V., Eindhoven (NL)

(21) Appl. No.: 13/248,805

(22) Filed: Sep. 29, 2011

(30) Foreign Application Priority Data
Sep. 30, 2010 (EP) 10012343.9
Sep. 30, 2010 (EP) 10275102.1

(51) Int. Cl. H04R 3/00; H03G 3/00

(52) U.S. Cl. 381/92; 381/107

(57) ABSTRACT

An audio-processing device having an audio input, for receiving audio signals, each audio signal having a mixture of components, each corresponding to a sound source, and a control input, for receiving, for each sound source, a desired gain factor associated with the source, by which it is desired to amplify the corresponding component, and an auxiliary signal generator, for generating at least one auxiliary signal from the audio signals, and with a different mixture of components as compared with a reference audio signal; and a scaling coefficient calculator, for calculating scaling coefficients based upon the desired gain factors and upon parameters of the different mixture, each scaling coefficient associated with one of the auxiliary signal and optionally the reference audio signal, and an audio synthesis unit, for synthesizing an output audio signal by applying scaling coefficients to the auxiliary signal and optionally the reference audio signal and combining the results.

This application claims the priority under 35 U.S.C. §119 of European patent application no. 10012343.9, filed on Sep. 30, 2010, and 10275102.1, filed on Sep. 30, 2010, the contents of which are incorporated by reference herein.

### FIELD OF THE INVENTION

This invention relates to manipulation of a sound scene comprising multiple sound sources. It is particularly relevant in the case of simultaneous recording of audio by multiple microphones.

### BACKGROUND OF THE INVENTION

Most existing sound scene manipulation methods operate in a two-stage fashion: in a first stage, the individual sound sources are extracted from one or more microphone recordings; and in a second stage, the separated sound sources are recombined according to the desired sound scene manipulation. When the manipulation consists of a change in the desired level of the individual sound sources (which is commonly the case), the second stage is trivial, once the first stage has been executed. Indeed, the recombination in the second stage then reduces to a simple linear combination of the separated sound sources obtained from the first stage. Unfortunately, the extraction of the individual sound sources from the recorded microphone signal(s) is a difficult problem, on which a lot of research effort has been spent. Broadly speaking, the state of the art in sound source extraction can be classified into three approaches:
1. Blind source separation (BSS): this approach allows for estimating a number of individual sound source components from a number of observed mixtures, by exploiting the statistical independence of the individual sources. Traditional BSS methods rely on the assumption that the number of sources is less than or equal to the number of observed mixtures, which implies that a potentially large number of microphones is required. Underdetermined BSS methods are capable of bypassing this condition, but they rely on a significant amount of prior knowledge regarding the individual sound sources. Since BSS methods tend to be computationally intensive, these are often not suited for real-time applications.
2. Computational auditory scene analysis (CASA): the aim of CASA is to analyze a sound scene in a way that mimics the human auditory system, by identifying and grouping perceptual attributes from the observed mixtures. Since CASA operates on two (binaural) microphone recordings, it is essentially an underdetermined BSS method as soon as the sound scene comprises more than two sources. While CASA has attracted the interest of many researchers, it is still considered not sufficiently mature to be used in real-life applications. Moreover, its computational requirements are typically very high.
3. Beamforming: this approach relies on the application of spatially selective filtering operations to two or more observed mixtures. There is no hard constraint on the number of observations required to separate a given number of sound sources, and moreover most beamforming implementations are computationally less demanding than the BSS or CASA approaches. However, beamforming either relies on prior knowledge about the sound source positions (in which case fixed beamformers can be applied) or requires a significant amount of additional processing for “supervision” (in the case of adaptive beamformers).

### SUMMARY OF THE INVENTION

According to an aspect of the present invention there is provided an audio-processing device comprising:
an audio input, for receiving one or more audio signals detected at respective microphones, each of the audio signals comprising a mixture of a plurality of components, each component corresponding to a sound source;
a control input, for receiving, for each sound source, a desired gain factor associated with the source, by which it is desired to amplify the corresponding component;
an auxiliary signal generator, adapted to generate at least one auxiliary signal from the one or more audio signals, the at least one auxiliary signal comprising a different mixture of the components as compared with a reference one of the one or more audio signals;
a scaling coefficient calculator, adapted to calculate a set of scaling coefficients in dependence upon the desired gain factors and upon parameters of the different mixture, each scaling coefficient associated with one of the at least one auxiliary signal and optionally the reference audio signal; and
an audio synthesis unit, adapted to synthesize an output audio signal by applying the scaling coefficients to the at least one auxiliary signal and optionally the reference audio signal and to combine the results,
wherein the scaling coefficients are calculated from the desired gain factors and the parameters of the different mixture such that the synthesized output signal provides the desired gain factor for each component.

A device according to an embodiment of the invention addresses the problem of sound scene manipulation from a fundamentally different perspective, in that it allows any specified level change to be performed for each of the individual sound source components in the observed mixture(s), without relying on an explicit sound source separation. The disadvantages overcome by the device as compared to the state of the art can be explained by considering each of the three approaches highlighted already above:
1. Advantages with respect to the BSS approach: similarly to the traditional BSS approach, the processing method implemented by the device requires as many different mixtures as the number of sound source levels that it is desired to alter independently. However, these mixtures can be generated from a smaller number of microphone recordings. For example, auxiliary mixtures can be generated by combining one microphone recording with one or more other microphone recordings. As a consequence, the method can also be used in scenarios with fewer microphones than sound sources, without a significant increase in computational burden. The proposed method has moderate computational complexity, which Increases only linearly with the number of observed microphone signal samples. It is thus particularly suited for real-time applications. Finally, the method does not rely on any prior knowledge about the statistics of the individual sound sources.
2. Advantages with respect to the CASA approach: whereas the CASA approach operates on a collection of auditory features of the sound sources, the present processing method operates directly on the observed microphone signals and on a number of auxiliary signals derived from these microphone signals. Consequently, the present method does not require the estimation and detection of auditory features, which is advantageous both in terms of robustness and in terms of computational complexity.
3. Advantages with respect to the beamforming approach: whereas the beamforming approach operates only on the observed microphone signals, the present method operates on a number of auxiliary signals in addition to the microphone signals. These auxiliary signals may be generated by combining the observed microphone signals. However, there is no restriction on the mapping from the observed microphone signals to the auxiliary signals, and hence the proposed method is much more flexible than the beamforming approach. As indicated below, one embodiment of the invention may include fixed as well as adaptive beamformers for generating the auxiliary signals from the microphone signals.

One application of a method or device according to an embodiment is the enhancement of acoustic signals like speech or music. In this case, the sound scene consists of desired as well as undesired sound sources, and the aim of the sound scene manipulation comprises reducing the level of the undesired sound sources relative to the level of the desired sound sources.

According to another aspect of the invention, there is provided a handheld personal electronic device comprising a plurality of microphones; and the audio processing device referred to above.

The invention is particularly suited to mobile, handheld applications, since it has relatively light computational demands. It may therefore be usable with a mobile device having limited processing resources or may enable power consumption to be reduced.

The mobile or handheld device preferably incorporates a video recording apparatus with a visual zoom capability, and the audio processing device is preferably adapted to modify the desired gain factors in accordance with a configuration of the visual zoom. This enables the device to implement an acoustic zoom function.

The microphones are preferably omni-directional microphones.

The present device may be particularly beneficial in these circumstances, because the source separation problem is inherently more difficult when using omni-directional microphones. If the microphones are uni-directional, there will often be significant selectivity (in terms of signal power) between the sources among the diverse audio signals. This can make the manipulation task easier. The present device is able to work also with omnidirectional microphones, where there will be less selectivity in the raw audio signals. The present device is therefore more flexible. For example, it can exploit spatial selectivity by means of beamforming techniques, but it is not limited to spatial selectivity through the use of unidirectional microphones.

According to a further aspect of the invention, there is provided a method of processing audio signals comprising:
receiving one or more audio signals detected at respective microphones, each of the audio signals comprising a mixture of a plurality of components, each component corresponding to a sound source;
receiving, for each sound source, a desired gain factor associated with the source, by which it is desired to amplify the corresponding component;
generating at least one auxiliary signal from the one or more audio signals, the at least one auxiliary signal comprising a different mixture of the components as compared with a reference one of the one or more audio signals;
calculating a set of scaling coefficients in dependence upon the desired gain factors and upon parameters of the different mixture, each scaling coefficient associated with one of the at least one auxiliary signal and optionally the reference audio signal; and
synthesizing an output audio signal by applying the scaling coefficients to the at least one auxiliary signal and optionally the reference audio signal and combining the results,
wherein the scaling coefficients are calculated from the desired gain factors and the parameters of the different mixture such that the synthesized output signal provides the desired gain factor for each component.

The parameters of the different mixture may be reweighting factors, which relate the levels of the components in the at least one auxiliary signal to their respective levels in the reference audio signal.

The method is particularly relevant to configurations with more than one microphone. Sound from all of the sound sources is detected at each microphone. Therefore, each sound source gives rise to a corresponding component in each audio signal. The number of sources may be less than, equal to, or greater than the number of audio signals (which is equal to the number of microphones). The sum of the number of audio signals and the number of auxiliary signals should be at least equal to the number of sources which it is desired to independently control.

Each auxiliary signal contains a different mixture of the components. That is, the components occur with different amplitude in each of the auxiliary signals (according to the reweighting factors). In other words, the auxiliary signals and the audio signals should be linearly independent; and the sets of reweighting factors which relate the signal components to each auxiliary signal should also be linearly independent of one another.

Explicit source separation is not necessary. Preferably the levels of the source signal components in the auxiliary signals are varied by a power ratio in the range −40 dB to +6 dB, more preferably −30 dB to 0 dB, still more preferably −25 dB to 0 dB, compared to their levels in the reference audio signal(s).

In the step of synthesizing the output signal, a scaling coefficient is preferably applied to the reference original audio signal and the result is combined with the scaled auxiliary signals.

The scaled auxiliary signals and/or scaled audio signals may be combined by summing them.

In general, in practice, the scaling coefficients and the desired gain factors will have different values (and may be different in number). They would only be identical if the auxiliary signals were to achieve perfect separation of the sources, which is usually impossible in practice. Each desired gain factor corresponds to the desired volume (amplitude) of a respective one of the sound-sources. On the other hand, the scaling coefficients correspond to the auxiliary signals and/or input audio signals. The number of reweighting factors is equal to the product of the number of signal components and the number of auxiliary signals, since in general each auxiliary signal will comprise a mixture of all of the signal components.

Preferably, the desired gain factors; the reweighting factors and the scaling coefficients are related by a linear system of equations; and the step of calculating the set of scaling coefficients comprises solving the system of equations.

For example, the step of calculating the set of scaling coefficients may comprise: calculating the inverse of a matrix of the reweighting factors; and multiplying the desired gain factors by the result of this inversion calculation.

The reweighting factors may be formed into a matrix and the inverse of this matrix may be calculated explicitly. Alternatively, the inverse may be calculated implicitly by equivalent linear algebraic calculations. The result of the inversion may be expressed as a matrix, though this is not essential.

The at least one auxiliary signal may be a linear combination of any of: one or more of the audio signals; one or more shifted versions of the audio signals; and one or more filtered versions of the audio signals.

The at least one auxiliary signal may be generated by at least one of: fixed beamforming; adaptive beamforming; and adaptive spectral modification.

Here, fixed beamforming means a spatially selective signal processing operation with a time-invariant spatial response. Adaptive beamforming means a spatially selective signal processing operation with a time-varying spatial response. Adaptive spectral modification means a frequency-selective signal processing operation with a time-varying frequency response, such as the class of methods known in the art as adaptive spectral attenuation or adaptive spectral subtraction. An adaptive spectral modification process typically does not exploit spatial diversity, but only frequency diversity among the signal components.

These are advantageous examples of ways to create the auxiliary signals. Fixed beamforming may be beneficial when there is some prior expectation that one or more of the sound sources is localised and located in a predetermined direction relative to a set of microphones. The fixed beamformer will then modify the power of the corresponding signal component, relative to other components.

Adaptive beamforming may be beneficial when a localised sound source is expected, but its orientation relative to the microphone(s) is unknown.

Adaptive spectral modification (for example, by attenuation) may be useful when sound sources can be discriminated to some extent by their spectral characteristics. This may be the case for a diffuse noise source, for example.

The methods of generating the auxiliary signal or signals are preferably chosen according to the expected sound environment in a given application. For example, if several sources in known directions are expected, it may be appropriate to use multiple fixed beamformers. If multiple moving sources are expected, multiple adaptive beamformers may be beneficial. In this way—as will be apparent to those skilled in the art—one or more instances of different means of generating the auxiliary signal may be combined, in embodiments.

Optionally, a first auxiliary signal is generated by a first method; a second auxiliary signal is generated by a second, different method; and the second auxiliary signal is generated based on an output of the first method.

For example, the fixed beamforming may be adapted to emphasize sounds originating directly in front of the microphone or microphone array. For example, this may be useful when the microphone is used in conjunction with a camera, because the camera (and therefore the microphone) is likely to be aimed at a subject who is one of the sound sources.

An output of the fixed beamformer may be input to the adaptive beamformer. This may be a noise reference output of the fixed beamformer, wherein the power ratio of a component originating from the fixed direction is reduced relative to other components. It is advantageous to use this signal in the adaptive beamformer, in order to find a (remaining) localised source in an unknown direction, because the burden on the adaptive beamformer to suppress the fixed signals may be reduced.

An output of the adaptive beamformer may be input to the adaptive spectral modification.

Typically, neither of the beamformers nor an adaptive spectral attenuator will be sufficiently selective to separate individual sources from the mixture. In this context, the method of the invention may be seen as a flexible framework for combining weak separators, to allow an arbitrary desired weighting on sound sources. The individual operations of beamforming or spectral modification preferably cause a change in the signal power of individual sound source components in the range −25 dB to 0 dB. This refers to the input/output power ratio of each operation, ignoring cascade effects due to the output of one unit being connected to the input of another

The method may optionally comprising: synthesizing a first output audio signal by applying scaling coefficients to a first reference audio signal and at least one first auxiliary signal and combining the results; and synthesizing a second output audio signal by applying scaling coefficients to a second, different reference audio signal and at least one second auxiliary signal and combining the results.

This may be particularly useful for generating binaural (for example, stereo) outputs. The at least one first auxiliary signal and at least one second auxiliary signal may be the same or different signals. The two different reference audio signals should be selected from appropriately arranged microphones, for a desired stereo effect.

In a similar way, the method can be extended to synthesize an arbitrarily greater number of outputs, as desired for any particular application.

The sound sources may comprise one or more localised sound sources and a diffuse noise field.

The desired gain factors may be time-varying.

The method is particularly well suited to real-time implementation, which means that the desired gain can be adjusted dynamically. This may be useful for example for dynamically balancing changing sound sources, or for acoustic zooming.

In a sound scene consisting of multiple desired sound sources, one often encounters the problem that the levels of the different sources are not sufficiently balanced in the microphone recordings—for example, if one of the sources is positioned closer to the microphone array than the others. In a static scenario, the sound scene can be balanced using time-invariant gain factors, while in a dynamic scenario (that is, with moving or temporally modulated sound sources) the use of time-varying gain factors is more relevant.

The desired gain factors can be chosen in dependence upon the state of a visual zoom function.

In applications where joint audio and video recordings are made (for example, camcorder or video-phone applications), it may be beneficial to match the auditory and visual cues in the recordings to obtain an easier and/or faster multisensory integration. A key example is the process of manipulating the sound scene such that it properly matches the video zooming operations. For example, when zooming in on a particular subject, the sound level of this subject should increase accordingly while keeping the level of the other sound sources constant. In this case, the desired gain factor corresponding to the sound source in front of the camera will be increased over time, while the other gain factors are time-invariant.

Also provided is a computer program comprising computer program code means adapted to perform all the steps of a method as described above, when said program is run on a computer; and such a computer program embodied on a computer readable medium.

### BRIEF DESCRIPTION OF THE DRAWINGS

The invention will now be described by way of example with reference to the accompanying drawings, in which:

FIG. 1 shows a block diagram of an audio processing device according to an embodiment;

FIG. 2 shows in greater detail an auxiliary signal generator and audio synthesis unit suitable for a monaural implementation of the embodiment of FIG. 1;

FIG. 3 shows in greater detail an auxiliary signal generator and audio synthesis unit suitable for a binaural (stereo) implementation of the embodiment of FIG. 1; and

FIG. 4 is a flowchart of a method according to an embodiment.

### DETAILED DESCRIPTION OF EMBODIMENTS

In the following, a theoretical explanation of a method according to an embodiment will first be given, along with an indication of the conditions under which this theory can be used for sound scene manipulation.

Consider a sound scene consisting of M localized sound sources sₘ(t), m=1, . . . , M positioned in different directions in the three-dimensional plane (as characterized by the azimuth-elevation angle pairs (θₘ,φₘ), m=1, . . . , M), in addition to a diffuse sound field that cannot be attributed to a single sound source or direction. Further to this, consider a microphone array consisting of N microphones (N≧2) and having an arbitrary three-dimensional geometry. Each of the microphones may have a different frequency- and angle-dependent response, as defined by

Aₙ(ω,θ,φ)=aₙ(ω,θ,φ)e^{-jψ}^{ₙ}^{(ω,θ,φ)}, n=0, . . . , N−1. (1)

The acoustic response (including the effect of the direct path time delay as well as reverberation) of a sound source at angle (θ,φ) to each of the microphones is given by

Fₙ(ω,θ,φ)=fₙ(ω,θ,φ)e^{-jξ}^{ₙ}^{(ω,ν,φ)}, n=0, . . . , N−1. (2)

For ease of notation, we introduce the joint acoustic and microphone response, defined as

Gₙ(ω,θ,φ)=Aₙ(ω,θ,φ)Fₙ(ω,θ, φ), n=0, . . . , N−1. (3)

Using the above definitions, we can express each of the N audio signals Uₙ(ω) detected at the microphones as a function of the localized sound sources and the diffuse sound field in the frequency domain as follows:

$${U}_{n} ( ω ) = {U}_{n}^{( 0 )} ( ω ) + {\sum }_{m = 1}^{M} \underbrace{{G}_{n} ( ω , {θ}_{m} , {φ}_{m} ) {S}_{m} ( ω )}_{{U}_{n}^{( m )} ( ω )} , n = 0 , … , N - 1 \qquad ( 4 )$$

where Uₙ⁽⁰⁾(ω) denotes the diffuse noise component. The above relation can equivalently be written in the time domain as follows,

$${u}_{n} ( t ) = {u}_{n}^{( 0 )} ( t ) + {\sum }_{m = 1}^{M} {u}_{n}^{( m )} ( t ) . \qquad ( 5 )$$

The aim of the envisaged sound scene manipulation is to produce N manipulated signals, or audio output signals, ζₙ(t), in which each of the levels of the individual sound source components is changed in a user-specified way as compared to the respective levels in the nth microphone signal. Mathematically, the aim is to produce the signals

$${ζ}_{n} ( t ) = {g}_{n}^{( 0 )} ( t ) {u}_{n}^{( 0 )} ( t ) + {\sum }_{m = 1}^{M} {g}_{n}^{( m )} ( t ) {u}_{n}^{( m )} ( t ) , n = 0 , … , N - 1 \qquad ( 6 )$$

where gₙ^{(m)}(t), m=0, . . . , M denote the user-specified time-varying gain factors for the different sound source components. Hereinafter, these will be referred to as the “desired gain factors”.

Suppose that one could generate M auxiliary signals xₙ^{(p)}(t), p=1, . . . , M, in which the different sound source components have been arbitrarily reweighted with respect to the corresponding components in the microphone signal uₙ(t), that is,

$${x}_{n}^{( p )} ( t ) = {\sum }_{m = 0}^{M} {γ}_{n}^{( p , m )} {u}_{n}^{( m )} ( t ) \qquad ( 7 )$$

Here, each of the reweighting factors is by definition equal to the square root of the power ratio of the corresponding sound source components, that is,

$${γ}_{n}^{( p , m )} = \frac{{σ}_{{x}_{n}^{( p )}}}{{σ}_{{u}_{n}^{( m )}}} = \sqrt{\frac{E \{ {( {x}_{n}^{( p )} )}^{2} \}}{E \{ {( {u}_{n}^{( m )} )}^{2} \}}} . \qquad ( 8 )$$

The nth manipulated signal (output audio signal) can now be calculated as a weighted sum of the nth microphone signal and the auxiliary signals xₙ^{(p)}(t), p=1, . . . , M defined above, that is,

$${ζ}_{n} ( t ) = {a}_{n}^{( 0 )} ( t ) {u}_{n} ( t ) + {\sum }_{p = 1}^{M} {a}_{n}^{( p )} ( t ) {x}_{n}^{( p )} ( t ) . \qquad ( 9 )$$

By using the relations in equations (5) and (7), the expression for the calculated nth manipulated signal in equation (9) can be shown to be equivalent to the expression for the desired nth manipulated signal in equation (6) if the weights aₙ^{(p)}, p=0, . . . , M satisfy the following relationship,

$$[ \begin{matrix}{a}_{n}^{( 0 )} ( t ) \\ {a}_{n}^{( 1 )} ( t ) \\ ⋮ \\ {a}_{n}^{( M )} ( t )\end{matrix} ] = \underbrace{{[ \begin{matrix}1 & {γ}_{n}^{( 1 , 0 )} & … & {γ}_{n}^{( M , 0 )} \\ 1 & {γ}_{n}^{( 1 , 1 )} & … & {γ}_{n}^{( M , 1 )} \\ ⋮ & ⋮ & ⋱ & ⋮ \\ 1 & {γ}_{n}^{( 1 , M )} & … & {γ}_{n}^{( M , M )}\end{matrix} ]}^{- 1}}_{{Γ}^{- 1}} [ \begin{matrix}{g}_{n}^{( 0 )} ( t ) \\ {g}_{n}^{( 1 )} ( t ) \\ ⋮ \\ {g}_{n}^{( M )} ( t )\end{matrix} ] \qquad ( 10 )$$

This implies that a unique set of weight trajectories aₙ^{(p)}(t), p=0, . . . , M, ∀t can be calculated that exactly produces the desired sound scene manipulation. Herein, the weight trajectories aₙ^{(p)}(t), p=0, . . . , M, ∀t are also referred to as “scaling coefficients”.

There are two conditions for exact reproduction of the effect of an arbitrary set of desired gain factors gₙ^{(m)}(t), according to equation (10):
1. The reweighting matrix Γ should be of full rank,
2. The reweighting factors γₙ^{(p,m)} should be known.

Loosely speaking, the first condition requires that the microphone signal uₙ(t) and the auxiliary signals xₙ^{(p)}(t), p=1, . . . , M should be linearly independent (which leads to linear independent columns Γ) and requires that the reweighting of the different sound source components in each of the auxiliary signals xₙ^{(p)}(t), p=1, . . . , M should be linearly independent (which leads to linear independent rows in Γ). The reweighting factors can be calculated or estimated depending on the embodiment of the invention, as described in greater detail below.

Note that equation (7) above is a model for the auxiliary signals which will usually be satisfied only approximately, in practice. In the embodiments described below, the auxiliary signals will be derived from the various microphone signals. Therefore, they will be composed of filtered versions of the sound source components, instead of the unfiltered (“dry”) sound source components themselves suggested by equation (7).

If the model of equation (7) could be satisfied precisely, exact recovery of a single sound source component would be possible (by choosing the desired gain factors appropriately). In the embodiment to be described below, this would demand the design of ideal beamformers that have a flat frequency response within the bandwidth of the source component of interest, and demand that the diffuse noise has no spectral overlap with the source component of interest. In practice, these restrictions are usually not met, and as a consequence the auxiliary signals will be linear combinations of filtered versions of the original sound source components (with non-uniform frequency response), rather than linear combinations of the original sound source components. This makes the exact recovery of a single sound source component impossible; however, this is a shortcoming of the practical embodiment rather than the theoretical method.

In the following, without loss of generality, an exemplary scenario will be considered in which the sound field in the acoustic environment is assumed to consist of four contributions coming from a different azimuthal directions:
1) a front sound source s_{F}(t), which is considered to be the desired sound source and is located in front of the camera at an angle θ_{F}=0 (by definition);
2) a back sound source s_{B}(t), which may or may not be a desired sound source, corresponding to the sound produced by the camera operator (if any) at an angle θ_{B}=180 degrees;
3) a number of localized interfering sound sources {s_{I}⁽ⁱ⁾(t)}N, i=1 which are considered to be undesired and originate from (unknown) directions θ_{I}(i) different from the front and back directions; and
4) a diffuse noise field, which cannot be attributed to a single sound source or direction, and which is also considered to be undesired.

The number of localized interfering sound sources is taken to be one, for the purposes of this explanation. Furthermore, in this example, it is assumed that the capture device is equipped with two or more microphones. Those skilled in the art will appreciate that none of these assumptions should be taken to limit the scope of the invention.

If the nth microphone signal uₙ(t) is decomposed in the time domain as:

uₙ(t)=uₙ^{(F)}(t)+uₙ^{(B)}(t)+uₙ^{(I)}(t)+uₙ^{(N)}(t)

then the corresponding desired output of the algorithm can be written as follows:

ζₙ(t)=gF(t)uₙ^{(E)}(t)+gB(t)uₙ^{(B)}(t)+gI(t)uₙ^{(I)}(t)+gN(t)uₙ^{(N)}(t)

where g_{F}(t), g_{B}(t), g_{I}(t), and g_{N}(t) denote the desired gain factors for the different sound source components. Note that one is not necessarily interested in calculating N output signals of the algorithm. Typically, the focus is on obtaining a mono or stereo output, which implies that the relation above only needs to be considered for one or two particular values of n, say n₁ (and n₂).

Nevertheless, all N microphone signals will typically be used to obtain an estimate of the two output signals, ζₙ_{₁}(t), ζₙ_{₂}(t). Also note that we have not included the output signal index n in the notation of the gain factors in the equation above, since typically the same gain factors will be used for the different output signals of the algorithm. (Of course, this is not essential).

Conventionally, it would be expected that the algorithm needs to perform some kind of source separation to isolate the different sound source components. However, since we are not interested in the separated sound source components, but rather in a mixture in which the levels of these components have been adjusted as compared to the microphone signals, an explicit source separation is not required. Let us denote three auxiliary signals as xₙ(t), yₙ(t), and zₙ(t), in which the different sound source components have been arbitrarily reweighted (by reweighting factors γ) with respect to the corresponding components in the microphone signal uₙ(t), that is:

xₙ(t)=γₓ_{ₙ}_{,u}_{ₙ}^{(F)}uₙ^{(F)}(t)+γₓ_{ₙ}_{,u}_{ₙ}^{(B)}uₙ^{(B)}(t)+γₓ_{ₙ}_{,u}_{ₙ}^{(I)}uₙ^{(I)}(t)+γₓ_{ₙ}_{,u}_{ₙ}^{(N)}uₙ^{(N)}(t)

yₙ(t)=γ_{y}_{ₙ}_{,u}_{ₙ}^{(F)}uₙ^{(F)}(t)+γ_{y}_{ₙ}_{,u}_{ₙ}^{(B)}uₙ^{(B)}(t)+γ_{y}_{ₙ}_{,u}_{ₙ}^{(I)}uₙ^{(I)}(t)+γ_{y}_{ₙ}_{,u}_{ₙ}^{(N)}uₙ^{(N)}(t)

zₙ(t)=γ_{z}_{ₙ}_{,u}_{ₙ}^{(F)}uₙ^{(F)}(t)+γ_{z}_{ₙ}_{,u}_{ₙ}^{(B)}uₙ^{(B)}(t)+γ_{z}_{ₙ}_{,u}_{ₙ}^{(I)}uₙ^{(I)}(t)+γ_{z}_{ₙ}_{,u}_{ₙ}^{(N)}uₙ^{(N)}(t).

The output signal of the algorithm can now be calculated as a linear combination of the nth microphone signal and the auxiliary signals xₙ(t), yₙ(t), and zₙ(t) defined above, that is:

ζₙ(t)=aₙ⁽⁰⁾(t)uₙ(t)+ aₙ⁽¹⁾(t)xₙ(t)+aₙ⁽²⁾(t)yₙ(t)+aₙ⁽³⁾(t)zₙ(t).

This corresponds to equation (9) above. The corresponding form of equation (10) is:

$$[ \begin{matrix}{a}_{n}^{( 0 )} ( t ) \\ {a}_{n}^{( 1 )} ( t ) \\ {a}_{n}^{( 2 )} ( t ) \\ {a}_{n}^{( 3 )} ( t )\end{matrix} ] = \underbrace{{[ \begin{matrix}1 & {γ}_{{x}_{n} , {u}_{n}}^{( F )} & {γ}_{{y}_{n} , {u}_{n}}^{( F )} & {γ}_{{z}_{n} , {u}_{n}}^{( F )} \\ 1 & {γ}_{{x}_{n} , {u}_{n}}^{( B )} & {γ}_{{y}_{n} , {u}_{n}}^{( B )} & {γ}_{{z}_{n} , {u}_{n}}^{( B )} \\ 1 & {γ}_{{x}_{n} , {u}_{n}}^{( I )} & {γ}_{{y}_{n} , {u}_{n}}^{( I )} & {γ}_{{z}_{n} , {u}_{n}}^{( I )} \\ 1 & {γ}_{{x}_{n} , {u}_{n}}^{( N )} & {γ}_{{y}_{n} , {u}_{n}}^{( N )} & {γ}_{{z}_{n} , {u}_{n}}^{( N )}\end{matrix} ]}^{- 1}}_{{Γ}^{- 1}} [ \begin{matrix}{g}_{F} ( t ) \\ {g}_{B} ( t ) \\ {g}_{I} ( t ) \\ {g}_{N} ( t )\end{matrix} ]$$

This enables the scaling factors, a, to be calculated, provided the re-weighting factors are known. The estimation of the re-weighting factors will be described in greater detail below. Before that, two embodiments of the invention will be described.

Both embodiments have the general structure shown in the block diagram of FIG. 1. An array of microphones 4 produces a corresponding plurality of audio signals 6. These are fed as input to an auxiliary signal generator 10. The auxiliary signal generator generates auxiliary signals, each comprising a mixture of the same sound source components detected by the microphones 4, but with the components present in the mixture with different relative strengths (as compared with their levels in the original audio signals 6). In the embodiments described below, these auxiliary signals are derived by processing combinations of the audio signals 6 in various ways. The auxiliary signals and the input audio signals 6 are fed as inputs to an audio synthesis unit 20. This unit 20 applies scaling coefficients to the signals and sums them, to produce output signals 40. In the output signals 40, the sound source components are present with desired strengths. These desired strengths are expressed by gain factors 8, which are input to a scaling coefficient calculator 30. The scaling coefficient calculator 30 converts the desired gains {g(t)} into a set of scaling coefficients {a(t)}. Each of the desired gains is associated with a sound source detectable at the microphones 4; whereas each of the scaling coefficients is associated with one of the auxiliary signals. The scaling coefficient calculator 30 exploits knowledge about the parameters of the auxiliary signals to transform from desired gains {g(t)} to suitable scaling coefficients {a(t)}.

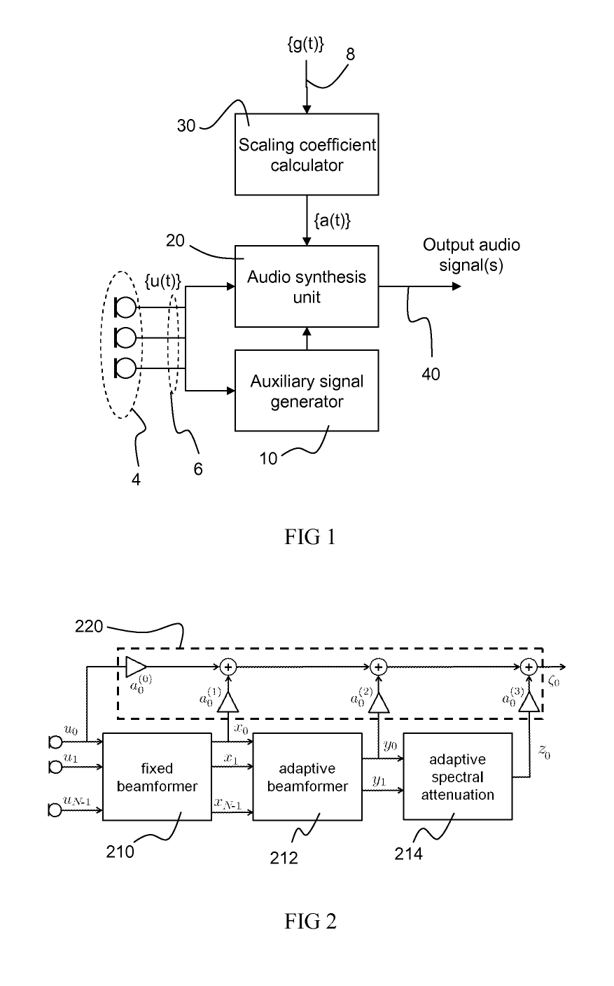

In the first embodiment the goal is to obtain a monaural (mono) output signal. FIG. 2 shows a block structure for the calculation of the auxiliary signals xₙ(t), yₙ(t), and zₙ(t) required in the algorithm.

In FIG. 2, the auxiliary signal generator 10 consists of three functional blocks 210, 212, 214:
1) Fixed beamformer 210: the purpose of this block is to perform reweighting of the sound source components of which the source direction is known a priori—that is, the front and back sound sources. The power ratios of these components are altered by the fixed beamformer, both relative to each other and relative to the other sound source components.
2) Adaptive beamformer 212: this block serves to perform reweighting of the localized interfering sound source(s). This necessarily requires an adaptive beamforming algorithm since the interfering sound source direction is unknown.
3) Adaptive spectral attenuation 214: this block reweights the diffuse noise field, by exploiting its assumed spectral diversity with reference to the localized sound source components.

The audio synthesis unit 20 is indicated by the dashed box 220. This produces the output signal ζ₀(t) as a weighted summation of the auxiliary signals x₀, y₀, and z₀, as well as the reference audio signal u₀. The weights are the scaling coefficients, a, derived by the scaling coefficient calculator 30 (not shown in FIG. 2).

Note that in the mono output case of FIG. 2, some of the auxiliary signals (more particularly xₙ(t) and yₙ(t) for n>0) are not explicitly used to calculate the output signal. However, these signals are used internally in the adaptive beamformer and adaptive spectral attenuation algorithms. More particularly, the signals xₙ(t), n>0 at the output of the fixed beamformer will be constructed to be “noise reference signals”; that is, signals in which the desired (front and optionally back) sound sources have been suppressed and which are used subsequently in the adaptive beamformer to estimate the localized interfering sound source component in the primary output signal x₀(t) of the fixed beamformer. The signal y₁(t) is then constructed to be a “diffuse noise reference” that is used by the adaptive spectral attenuation algorithm to estimate the diffuse noise component in the primary output signal y₀(t) of the fixed beamformer.

Because of the above discrimination between the primary beamformer output signals x₀(t) and y₀(t), on the one hand; and the other beamformer output signals xₙ(t) and yₙ(t) with n>0, on the other hand, a stereo output signal should preferably not be created by calculating ζ₀(t) and ζ₁(t) using these auxiliary signals.

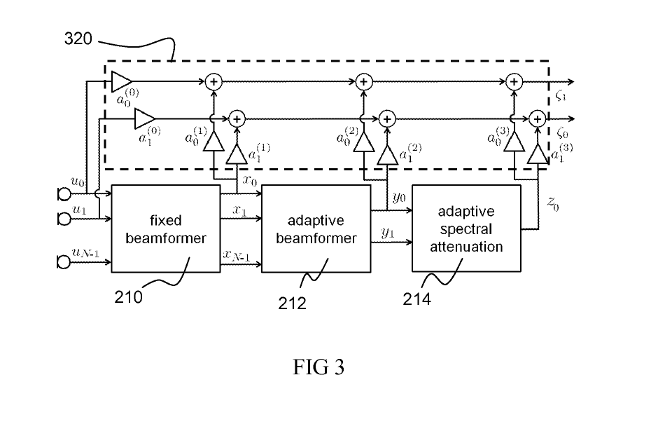

Instead, in the second embodiment, the block structure shown in FIG. 3 is used for the stereo case. Here, the stereo output signals are calculated as follows:

ζ₀(t)=a₀⁽⁰⁾(t)u₀(t)+a₀⁽¹⁾(t)x₀(t)+a₀⁽²⁾(t)y₀(t)+a₀⁽³⁾(t)z₀(t)

ζ₁(t)=a₁⁽⁰⁾(t)u₁(t)+a₁⁽¹⁾(t)x₀(t)+a₁⁽²⁾(t)y₀(t)+a₁⁽³⁾(t)z₀(t)

That is, the same set of auxiliary signals is used for generating both stereo outputs, but a different reference audio signal, uₙ(t), is used in each case. This computation is performed by the audio synthesis unit 320 indicated by the dashed box.

In the case that N>2 (that is, when the array consists of more than two microphones), one should select u₀(t) and u₁(t) to be those two microphone signals that are best suited to deliver a stereo image. As will be apparent to those skilled in the art, this will typically depend on the placement of the microphones.

Note that, due to the particular structure shown in FIG. 5, the weight calculation for the second output signal ζ₁(t) should be slightly altered, to:

$$[ \begin{matrix}{a}_{1}^{( 0 )} ( t ) \\ {a}_{1}^{( 1 )} ( t ) \\ {a}_{1}^{( 2 )} ( t ) \\ {a}_{1}^{( 3 )} ( t )\end{matrix} ] = \underbrace{{[ \begin{matrix}1 & {γ}_{{x}_{0} , {u}_{1}}^{( F )} & {γ}_{{y}_{0} , {u}_{1}}^{( F )} & {γ}_{{z}_{0} , {u}_{1}}^{( F )} \\ 1 & {γ}_{{x}_{0} , {u}_{1}}^{( B )} & {γ}_{{y}_{0} , {u}_{1}}^{( B )} & {γ}_{{z}_{0} , {u}_{1}}^{( B )} \\ 1 & {γ}_{{x}_{0} , {u}_{1}}^{( I )} & {γ}_{{y}_{0} , {u}_{1}}^{( I )} & {γ}_{{z}_{0} , {u}_{1}}^{( I )} \\ 1 & {γ}_{{x}_{0} , {u}_{1}}^{( N )} & {γ}_{{y}_{0} , {u}_{1}}^{( N )} & {γ}_{{z}_{0} , {u}_{1}}^{( N )}\end{matrix} ]}^{- 1}}_{{Γ}^{- 1}} [ \begin{matrix}{g}_{F} ( t ) \\ {g}_{B} ( t ) \\ {g}_{I} ( t ) \\ {g}_{N} ( t )\end{matrix} ]$$

Meanwhile, the weights for the primary output signal ζ₁(t) can be calculated as before, with n=0.

As the equations above show, the scaling coefficient calculator 30 uses knowledge of the reweighting factors γₙ^{(p,m)} to derive the scaling coefficients, a(t), from the desired gains, g(t). In the presently described embodiments, the reweighting factors are found by using knowledge of the characteristics of the various blocks 210, 212, 214 in the auxiliary signal generator. Preferably, the reweighting factors are determined offline.

Examples of the calculation of the reweighting factors will be described below. These examples rely on a frequency-domain characterisation of the auxiliary signal generator blocks 210, 212, 214.

The input-output relation of the three functional blocks in the block structure can be described in the frequency domain as follows. The fixed beamformer can be specified by an N×N transfer function matrix W₁(ω), that is,

$$X ( ω ) = {W}_{1}^{H} ( ω ) U ( ω )$$

$$where$$

$$X ( ω ) = {[ {X}_{0} ( ω ) … {X}_{N - 1} ( ω ) ]}^{T }$$

$${W}_{1} ( ω ) = [ \begin{matrix}{W}_{1 , ( 1 , 1 )} ( ω ) & … & {W}_{1 , ( 1 , N )} ( ω ) \\ ⋮ & ⋱ & ⋮ \\ {W}_{1 , ( N , 1 )} ( ω ) & … & {W}_{1 , ( N , N )} ( ω )\end{matrix} ]$$

and U(ω) is defined as

U(ω)=[U₀(ω) . . . U_{N-1}(ω)]^{T}

The adaptive beamformer can be specified by an N×1 transfer function vector W₂(ω) that defines the relation between the adaptive beamformer input and its primary output signal:

Y₀(ω)=w₂^{H}(ω)×(ω)

where

w₂(ω)=[w_{2,(1)}(ω) . . . w_{2,(N)}(ω)]^{T}

As explained earlier, the secondary adaptive beamformer output signal should ideally be an estimate of the diffuse noise component in the primary adaptive beamformer output signal. The most straightforward approach is to choose the secondary output signal to be equal to one of the noise references at the output of the fixed beamformer—for example, Y₁(ω)=X₁(ω). Alternatively, one could attempt to remove the localized interfering sound source component from the secondary adaptive beamformer output signal, however, this approach is not used in the present embodiments. The adaptive spectral attenuation can finally be specified using a scalar transfer function W₃(ω), that is,

Z₀(ω)=Wₑ(ω)Y₀(ω)

Using the above input-output relations, we can derive expressions for the different localized sound source components in the primary auxiliary signals X₀(ω), Y₀(ω), and Z₀(ω) as a function of the corresponding dry sound source signals S_{F}(ω), S_{B}(ω), and S_{I}(ω),

X₀^{(c)}(ω)=w_{1,(:,1)}^{H}(ω)G(ω,θ_{c})S_{c}(ω)

Y₀^{(c)}(ω)=w₂^{H}(ω)w₁^{H}(ω)G(ω,θ_{c})S_{c}(ω)

Z₀^{(c)}(ω)=w₃(ω)w₂^{H}(ω)w₁^{H}(ω)G(ω,θ_{c})S_{c}(ω)

where c represents the component F, B, or I, and w_{1,(:,1)}(ω) denotes the first column of W₁(ω). Similarly, the diffuse noise component in the primary auxiliary signals can be expressed as a function of the diffuse noise components in the microphone signals,

X₀^{(N)}(ω)=w_{1,(:,1)}^{H}(ω)U^{(N)}(ω)

Y₀^{(N)}(ω)=w₂^{H}(ω)w₁^{H}(ω)U^{(N)}(ω)

Z₀^{(N)}(ω)=w₃(ω)w₂^{H}(ω)w₁^{H}(ω)U^{(N)}(ω)

We will now make the following assumptions, to simplify the calculation of the reweighting factors:
1) the joint acoustic and microphone responses have a flat magnitude response within the bandwidth and in the direction of the different sound source components, i.e.,

∀ω: S_{c}(ω)≠0, Uₙ^{(N)}(ω)≠0 [symbol] |Gₙ(ω,θ_{c})|≡|Gₙ(θ_{c})|, n=0 , . . . , N−1, c=F,B,I
2) the fixed and adaptive beamformers have a flat magnitude response within the bandwidth and in the direction of the different sound source components, that is,

$$∀ ω : {S}_{c} ( ω ) \neq 0 , {U}_{n}^{( N )} ( ω ) \neq 0 ⇒ \{ \begin{matrix}\vert {W}_{1 , ( m , n )} ( ω ) \vert ≡ \vert {W}_{1 , ( m , n )} \vert , \\ \vert {W}_{2 , ( n )} ( ω ) \vert ≡ \vert {W}_{2 , ( n )} \vert ,\end{matrix} \\ m = 1 , … , N , n = 1 , … , N , c = F , B , I$$

3) the diffuse noise spectrum does not overlap with the spectra of the different localized sound sources,

[symbol]

ω: S_{c}(ω)≠0 & Uₙ^{(N)}(ω)≠0, n=0, . . . , N−1, c=F,B,I
4) the adaptive spectral attenuation magnitude response is flat within the bandwidth of the localized sound sources and within the bandwidth of the diffuse noise,

∀ω: S_{c}(ω)≠0 [symbol] |W₃(ω)|≡|W₃^{(c)}|, c=F,B,I

∀ω: \dot{U}ₙ^{(N)}(ω)≠0 [symbol] |W₃(ω)|≡|W₃^{(N)}|, n=0, . . . , N−1
5) the diffuse noise power in each of the microphone signals is equal,

σᵤ_{₀}_{^{(N)}}²= . . . . =σᵤ_{_{N-1}}_{^{(N)}}²

Under these assumptions, the signal powers of the different sound source components in the microphone and auxiliary signals can be estimated as follows:

σᵤ_{ₙ}_{^{(e)}}²=|Gₙ(θ_{c})|²σₛ_{ₑ}²; n=0, . . . , N−1, c=F,B,I

σₓ_{₀}_{^{(e)}}²=|W_{1,(:,1)}^{H}G(θ_{c})|²σₛ_{_{c}}², c=F,B,I

σ_{y}_{₀}_{^{(c)}}²=|W₂^{H}W₁^{H}G(θ_{c})|²σₛ_{_{c}}², c=F,B,I

σ_{z}_{₀}_{^{(e)}}²=|W₃^{(c)}|²|W₂^{H}W₁^{H}G(θ_{c})|²σₛ_{_{c}}²; c=F,B,I

σₓ_{₀}_{^{(N)}}²=∥W_{1,(:,1)}∥₂²σᵤ_{₀}_{^{(N)}}²

σ_{y}_{₀}_{^{(N)}}²=∥W₁W₂∥₂²σᵤ_{₀}_{^{(N)}}²

σₓ_{₀}_{^{(N)}}²=∥W₃^{(N)}|²∥W₁W₂∥₂²σᵤ_{₀}_{^{(N)}}²

and consequently, the reweighting factors can be calculated as

$${γ}_{{x}_{0} , {u}_{n}}^{( c )} = \frac{\vert {W}_{1 , ( : , 1 )}^{H} G ( {θ}_{c} ) \vert}{\vert {G}_{n} ( {θ}_{c} ) \vert} , n = 0 , … , N - 1 , c = F , B , I$$

$${γ}_{{y}_{0} , {u}_{n}}^{( c )} = \frac{{W}_{2}^{H} {W}_{1}^{H} G ( {θ}_{c} )}{\vert {G}_{n} ( {θ}_{c} ) \vert} , n = 0 , … , N - 1 , c = F , B , I$$

$${γ}_{{z}_{0} , {u}_{n}}^{( c )} = \frac{\vert {W}_{3}^{( c )} \vert \vert {W}_{2}^{H} {W}_{1}^{H} G ( {θ}_{c} ) \vert}{\vert {G}_{n} ( {θ}_{c} ) \vert} , n = 0 , … , N - 1 , c = F , B , I$$

$${γ}_{{x}_{0} , {u}_{n}}^{( N )} = {‖ {W}_{1 , ( : , 1 )} ‖}_{2} , n = 0 , … , N - 1$$

$${γ}_{{y}_{0} , {u}_{n}}^{( N )} = {‖ {W}_{1} {W}_{2} ‖}_{2} , n = 0 , … , N - 1$$

$${γ}_{{z}_{0} , {u}_{n}}^{( N )} = \vert {W}_{3}^{( N )} \vert {‖ {W}_{1} {W}_{2} ‖}_{2} , n = 0 , … , N - 1$$

Finally, note that from a computational point of view, in some applications, it may be undesirable to calculate the reweighting factors online (in real-time) using the preceding formulae. A more efficient approach involves setting the values of the reweighting factors off-line (in advance), making use of the fixed beamformer response (known a priori) and of heuristics about the behaviour of the adaptive beamformer and spectral attenuation response. The values chosen can be approximations of the theoretical values predicted by the equations above. For example, the values may be set heuristically in 5 dB steps. In many applications, the method will be largely insensitive to 5 dB or 10 dB deviations from the precise theoretical values.

The design of the fixed beamformer in an exemplary embodiment will now be described.

As explained previously above, the fixed beamformer creates a primary output signal X₀(ω) that spatially enhances the front sound source signal, as well as a number of other output signals Xₙ(ω), n>0 that serve as “noise references” for the adaptive beamformer. Here, we will first discuss the design of the so-called front source beamformer (FSB), and afterwards we will explain the design of the so-called blocking matrix (BM).

Depending on the kind of spatial enhancement one wants to achieve for the front sound source, different fixed beamformer design methods could be employed for the FSB; for example, an array pattern synthesis approach, or a differential or superdirective design method. These methods themselves are known in the art. In the present embodiment, we will adopt a superdirective (SD) design method, which is recommendable when the aim is to maximize the directivity factor of the microphone array—that is, to maximize the array gain in the presence of a diffuse noise field. The frequency-domain SD design equation for the FSB can be found in S. Doclo and M. Moonen (“Superdirective beamforming robust against microphone mismatch,” IEEE Trans. Audio Speech Lang. Process., vol. 15, no. 2, pp. 617-631, February 2007):

$${W}_{1 , ( : , 1 )} ( ω ) = \frac{{( {\tilde{Φ}}_{U}^{( N )} + μ {I}_{N} )}^{- 1} G ( ω , {θ}_{F} )}{{G}^{H} ( ω , {θ}_{F} ) {( {\tilde{Φ}}_{U}^{( N )} + μ {I}_{N} )}^{- 1} G ( ω , {θ}_{F} )}$$

where G(ω, θ_{F}) denotes the front sound source steering vector

G(ω,θ)=[G₀(ω,θ) . . . G_{N-1}(ω,θ)]^{T}

I_{N} represents the N×N identity matrix, μ is a regularization parameter, and Φ̅_{U}^{(N)} denotes the normalized diffuse noise correlation matrix, which can be calculated from the joint acoustic and microphone responses as follows,

$${\tilde{Φ}}_{U}^{( N )} = [ \begin{matrix}{\tilde{Φ}}_{{U}_{o} , {U}_{o}}^{( N )} & … & {\tilde{Φ}}_{{U}_{o} , {U}_{N - 1}}^{( N )} \\ ⋮ & ⋱ & ⋮ \\ {\tilde{Φ}}_{{U}_{N - 1} , {U}_{o}}^{( N )} & … & {\tilde{Φ}}_{{U}_{N - 1} , {U}_{N - 1}}^{( N )}\end{matrix} ]$$

$$with$$

$${\tilde{Φ}}_{{U}_{m} , {U}_{n}}^{( N )} = \frac{1}{2 π} {\int }_{0}^{2 π} {G}_{m} ( ω , θ ) {G}_{n}^{*} ( ω , θ ) d θ$$

The directivity factor (DF) and the ratio of the front and back response (FBRR) of the SD beamformer are defined as follows:

$$DF [ dB ] = 10 {log}_{10} ( \frac{1}{2 π} {\int }_{0}^{2 π} \frac{{\vert {W}_{1 , ( : , 1 )}^{H} ( ω ) G ( ω , {θ}_{F} ) \vert}^{2}}{{W}_{1 , ( : , 1 )}^{H} ( ω ) {\tilde{Φ}}_{U}^{( N )} {W}_{1 , ( : , 1 )} ( ω )} d ω )$$

$$FBRR [ dB ] = 10 {log}_{10} ( \frac{{\int }_{0}^{2 π} {\vert {W}_{1 , ( : , 1 )}^{H} ( ω ) G ( ω , {θ}_{F} ) \vert}^{2} d ω}{{\int }_{0}^{2 π} {\vert {W}_{1 , ( : , 1 )}^{H} ( ω ) G ( ω , {θ}_{B} ) \vert}^{2} d ω} ) .$$

Whereas the DF is nearly constant with FSB filter length, the FBRR increases for higher filter lengths and approximately saturates for a length greater than or equal to 128. Note that the frequency-domain SD design is executed at L_{FSB}/2 frequencies that are uniformly distributed in the Nyquist interval, after which the frequency-domain FSB coefficients are transformed to length-L_{FSB} time-domain filters. Experiments have also shown a significant performance gap between the 2-mic configuration and other configurations, with greater than 2 microphones, both in terms of directivity and FBRR.

The BM in the fixed beamformer consists of a number of filter-and-sum beamformers that each operate on one particular subset of microphone signals. In this way, a number of noise reference signals is created, in which the power of the desired signal components is maximally reduced relative to the power of these components in the microphone signals. Typically, in an N-microphone configuration, N-1 noise references are created by designing N-1 different filter-and-sum beamformers. However, in some cases it might be preferable to create fewer than N-1 noise references, which then leads to a reduction of the number of input signals xₙ(t) for the adaptive beamformer. In fact, in this embodiment we employ a BM consisting of only one filter-and-sum beamformer designed using the complete set of available microphone signals. In this way, the number of adaptive filters and hence the computational complexity of the adaptive beamformer can be considerably reduced.

In the context of the BM design, we consider the back sound source (if any) to be an undesired signal (which should be cancelled by the adaptive beamformer); hence the BM design reduces to a front-cancelling beamformer (FCB) design. Again, one of several different fixed beamformer design methods can be employed. In this embodiment, we use an array pattern synthesis method, different from existing methods.

In general, we can specify the frequency-domain FCB design at a set of angles {θ₀, . . . , θ_{M-1}} by the following linear system of equations:

$$\underbrace{[ \begin{matrix}{G}_{0}^{*} ( ω , {θ}_{0} ) & … & {G}_{N - 1}^{*} ( ω , {θ}_{0} ) \\ ⋮ & ⋱ & ⋮ \\ {G}_{0}^{*} ( ω , {θ}_{M - 1} ) & … & {G}_{N - 1}^{*} ( ω , {θ}_{M - 1} )\end{matrix} ]}_{{G}^{H} ( ω )} {W}_{1 , ( : , 2 )} ( ω ) = \underbrace{[ \begin{matrix}{P}_{0}^{*} ( ω ) \\ ⋮ \\ {P}_{M - 1}^{*} ( ω )\end{matrix} ]}_{{P}^{*} ( ω )}$$

where Pₘ(ω), m=0 , . . . . , M-1 denotes the desired response at frequency ω and angle θₘ. The least-squares (LS) optimal solution is then given by

w_{1,(:,2)}(ω)=[ G̅(ω) G̅^{H}(ω)]⁻¹ G̅(ω)P*(ω)

More specifically, to obtain an FCB design we should specify a zero response in the front direction and a non-zero response in any other direction. Preferably the latter direction should the back direction to avoid that the design would actually correspond to a front-back-cancelling beamformer design. As a consequence, the number of equations in the linear system of equations above is M=2, and the specification angles correspond to θ₀=θ_{F} and θ₁=θ_{B}. Finally, the desired response vector is equal to P*(ω)=[0,1]^{H}.

With this design, the back response is indeed close to a unity response for most microphone configurations and filter length values. However, the front source response varies heavily according to the microphone configuration and filter length used. An important observation is that at least one microphone pair in an endfire configuration should preferably be included in the array to obtain a satisfactory power reduction of the front sound source component. Concerning the choice of the BM filter length, experiments show that there is no clear threshold effect—that is, the response in the front direction decreases with a nearly constant slope (provided an endfire microphone pair is included). As a consequence, the BM filter length should preferably be chosen according to the desired front sound source power reduction.

The design of the adaptive beamformer in an exemplary embodiment will now be described.

The adaptive beamformer in the block scheme may be implemented using a generalized sidelobe canceller (GSC) algorithm; a multi-channel Wiener filtering (MWF) algorithm; or any other adaptive algorithm. In this embodiment, we employ the speech-distortion-weighted multi-channel Wiener filtering (SDW-MWF) which includes the GSC and MWF as special cases. Details of this method can be found in S. Doclo, A. Spriet, J. Wouters, and M. Moonen (“Frequency-domain criterion for the speech distortion weighted multichannel wiener filter for robust noise reduction,” Speech Commun., vol. 49, no. 7-8, pp. 636-656, July-August 2007, special Issue on Speech Enhancement).

The objective of the SDW-MWF is to jointly minimize the energy of the undesired components (B, I, N) and the distortion of the desired component (F) in the enhanced signal Y₀(ω). That is,

$${min}_{{W}_{2} ( ω )} E \{ {\vert {W}_{2}^{H} ( ω ) [ {X}^{( B )} ( ω ) + {X}^{( I )} ( ω ) + {X}^{( N )} ( ω ) ] \vert}^{2} \} + \frac{1}{μ} E \{ {\vert {X}_{0}^{( F )} ( ω ) - {W}_{2}^{H} ( ω ) {X}^{( F )} ( ω ) \vert}^{2} \}$$

resulting in the adaptive beamformer estimate

w₂(ω)=[Φₓ^{(F)}(ω)+μΦₓ^{(B,I,N)}(ω)]⁻¹Φₓ^{(F)}(ω)e₀

where e₀ [symbol] [1, 0, . . . , 0]^{T} and the correlation matrices of the desired and undesired components in the adaptive beamformer input signal are defined as

Φₓ^{(F)}(ω)=E{[X^{(F)}(ω)][X^{(F)}(ω)]^{H}}

Φₓ^{(B,I,N)}(ω)=E{[X^{(B)}(ω)+X^{(I)}(ω)+X^{(N)}(ω)][X^{(B)}(ω)+X^{(I)}(ω)+X^{(N)}(ω)]^{H}}

The parameter μ can be tuned to trade off energy reduction of the undesired components versus distortion of the desired component. Several recursive implementations of the SDW-MWF filter estimate have been proposed, in which the adaptive SDW-MWF filter update is based on a generalized singular value decomposition (GSVD), a QR decomposition (QRD), a time-domain stochastic gradient method, or a frequency-domain stochastic gradient method. A common feature of these implementations is that the correlation matrices Φₓ^{(F)}(ω) and Φₓ^{(B,I,N)}(ω) are explicitly estimated before the SDW-MWF filter estimate is computed.

The signal-to-noise ratio (SNR) improvement provided by the SDW-MWF adaptive beamformer has been evaluated in a scenario with two localized sound sources: a front sound source consisting of a male speech signal (θ_{F}=0) and a localized interfering sound source consisting of a music signal (θ_{I}=90 degrees).

The mean SNR at the microphones is equal to 10 dB. The fixed beamformer is implemented using a SD design for the FSB and a front-cancelling design for the BM, and an evaluation is done both for L_{FSB}=L_{BM}=64 and for L_{FSB}=L_{BM}=128. The adaptation of the SDW.-MWF algorithm is based on a stochastic gradient frequency-domain implementation, and is controlled by a perfect (manual) voice activity detection (VAD). Two features of the SDW-MWF have been evaluated, namely:
1) the use of a feedforward filter W_{2,(1)}(ω) to include the fixed beamformer primary output signal X₀(ω) as an additional noise reference in the adaptive beamformer; and
2) the value of the SDW-MWF trade-off parameter 1/μ (where 1/μ=0 means no penalization of the desired component distortion).

Note that in case the desired component distortion is not penalized (1/μ=0), the algorithm without a feedforward filter corresponds to the GSC algorithm, while the algorithm with a feedforward filter is not relevant due to an intolerable speech distortion. The evaluation has shown that the GSC algorithm as well as the SDW-MWF algorithm with a small trade-off parameter (1/μ=0.01) are well suited for the reduction of the localized interfering sound source power. Moreover, there appears to be no significant influence of the number of microphones and the FSB and BM filter lengths on the adaptive beamformer performance.

The design of the Adaptive Spectral Attenuation process in an exemplary embodiment will now be described.

The adaptive spectral attenuation block is included in the structure with the aim of reducing the diffuse noise energy in the primary adaptive beamformer output signal. To this end, the short-term magnitude spectra of the reference microphone signal, |U₀(ωₖ, l)|, and the primary and secondary adaptive beamformer output signals, |Y₀(ωₖ, l)| and |Y₁(ωₖ, l)|, are estimated by means of a Discrete Fourier transform (DFT), with k and l denoting the DFT frequency bin and time frame indices. An instantaneous spectral gain function is then calculated as follows,

$${G}_{inst} ( {ω}_{k} , l ) = \frac{\vert {U}_{0} ( {ω}_{k} , l ) \vert - {β}_{n} \hat{C} ( {ω}_{k} , l ) \vert {\hat{Y}}_{1} ( {ω}_{k} , l ) \vert}{\vert {\hat{Y}}_{0} ( {ω}_{k} , l ) \vert + ɛ}$$

where the subtraction factor βₙ ∈ [0,1] determines the amount of spectral attenuation and the regularization factor ε is a small constant which prevents division by zero. Since the secondary adaptive beamformer output signal Y₁(ω) is equal to the noise reference X₁(ω) at the output of the fixed beamformer, a spectral coherence function C(ωₖ,l) that relates the magnitude spectra of the diffuse noise components in the primary and secondary fixed beamformer output signals needs to be estimated and taken into account in the equation. The instantaneous gain function of the equation is then lowpass filtered and clipped, before being applied to the speech estimate, that is,

Gₗₚ(Ωₖ,l)=(1−α)Gₗₚ(ωₖ,l−1)+αGᵢₙₛₜ(ωₖ,l)

G(ωₖl)=max{Gₗₚ(ωₖ,l),ξₙ}

|Z(ωₖ,l)|=G(ωₖ,l)|Y₀(ωₖ,l)|

where α denotes the lowpass filter pole and ξₙ=1−βₙ is the clipping level. The enhanced signal magnitude spectrum |Z(ωₖ,l)| is subsequently transformed back to the time domain by applying an inverse DFT (IDFT), and by using the phase spectrum of the primary adaptive beamformer output signal Y₀(ωₖ,l).

An exemplary use of the embodiment in an Acoustic Zoom (AZ) application will now be described.
1) Specification of the time-varying gain factors: In the AZ application, the aim is to keep the level of the undesired sound sources constant, while the level of the desired sound sources should adapt to the camera zoom state. As a consequence, we should set the gain factors for the localized interfering sound source and the diffuse noise as follows,

gI(t)≡1

gN(t)≡1

From preliminary results with the above zoom-in trajectory for the front sound source level, it was noted that a perceptually better trajectory could be designed. More particularly, a faster level increase at the start of the zoom-in operation would be desired, eventually converging to the same final level at close-up. A perceptually more attractive level trajectory was found to be

$${g}_{F} ( t ) = 1 + \frac{{2}^{{d}_{zoom}} - 1}{\sqrt{1.2 {d}_{zoom}}} \sqrt{1.2 {υ}_{zoom} t} , 0 \leq t \leq \frac{{d}_{zoom}}{{υ}_{zoom}}$$

Concerning the specification of the back sound source gain factor, several possibilities exist. A first possibility is to regard the back sound source as an undesired sound source, in which case its level should remain constant. However, since the back sound source is typically very close to the camera, its level should often be reduced to obtain an acceptable balance between the back sound source and the other sound sources. A second possibility is to have the back sound source gain factor follow the inverse trajectory of the front sound source gain factor, possibly combined with a fixed back sound source level reduction. While such an inverse level trajectory would obviously make sense from a physical point of view, it may be perceived somewhat too artificial, since the front sound source level change is then supported by visual cues, while the back sound source level change is not.

Experiments have been performed to demonstrate the performance of the AZ algorithm. In both experiments, the front sound source is a male speech signal corresponding to a camera recording that consists of a far shot phase (5 s), a zoom-in phase (10 s), and a close-up phase (11 s). In addition, the sound field consists of diffuse babble noise and a localized interfering music source at θ_{I}=90 deg. In the first simulation, no back sound source is present, while in the second simulation, a female speech signal is present in the back direction (θ_{B}=180 deg).

A 3-microphone array was used, employing microphones 1,3, and 4 as indicated in FIG. 1. The fixed beamformer consists of a superdirective FSB and a single-noise-reference front-cancelling BM, both a with filter length of 64. The adaptive beamformer is calculated using a GSC algorithm and has a filter length of 128. The desired AZ effect consists in keeping the level of the undesired sound sources (including the back sound source in the second simulation) unaltered, while increasing the level of the front sound source during the zoom-in phase, according to the perceptually optimal trajectory defined above.

In these embodiments the values of the re-weighting factors were determined empirically in advance, rather than at run-time (as described previously above).

As will be apparent to those skilled in the art, the performance of the method depends in part upon the accuracy to which the reweighting factors can be estimated. The greater the accuracy, the better the performance of the manipulation will be.

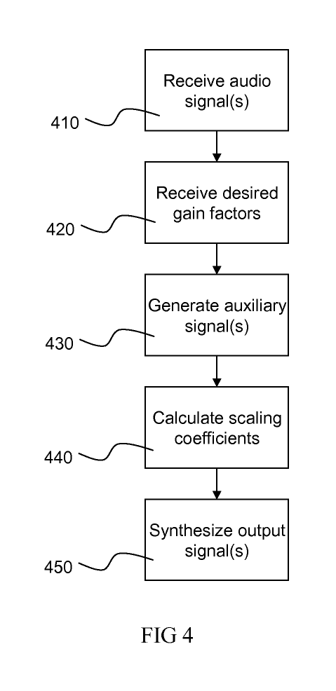

FIG. 4 is a flowchart summarising a method according to an embodiment. In step 410, audio signals 6 are received from the microphones 4. In step 420, the desired gain factors 8 are input. In step 430, the auxiliary signal generator generates the auxiliary signals. In step 440, the scaling coefficient calculator 30 calculates the scaling coefficients, a(t). Finally, in step 450, the audio synthesis unit 20 applies the scaling coefficients to the generated auxiliary signals and reference audio signals, to synthesise output audio signals 40.

While the invention has been illustrated and described in detail in the drawings and foregoing description, such illustration and description are to be considered illustrative or exemplary and not restrictive; the invention is not limited to the disclosed embodiments.

For example, it is possible to operate the invention in an embodiment wherein different blocks are used to generate the auxiliary signals. The exemplary blocks described above (fixed or adaptive beamforming, or adaptive spectral modification) can be replaced or supplemented by other methods. Essentially, the auxiliary signal calculation should be such that it exploits the diversity of the individual sound sources in the sound scene. When multiple microphones are used, then exploiting spatial diversity is often the most straightforward option—and this is exploited by the beamformers in the embodiments described above. However, different kinds of diversity could equally be exploited, for example: diversity in the time domain (if not all of the sound sources are concurrently active); diversity in statistics (which could lead to the use of Wiener filtering, independent component analysis, and so on); or diversity in the degree of (non-)stationarity. The optimal choice of auxiliary signal generator will vary according to the application and the characteristics of the audio environment.

The ordering of the blocks described in embodiments herein and shown in the drawings is also not limiting on the scope of the invention. Blocks may be eliminated, re-ordered or duplicated.

Likewise, although the embodiments described herein have concentrated on monaural or stereo implementation, the invention can of course be implemented with a greater number of audio output signals than just one or two. Those skilled in the art will be readily able to generalise from the description above, to provide an arbitrary number of desired outputs. This may be useful, for example, for multi-channel or surround-sound audio applications.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfil the functions of several items recited in the claims. The mere fact that certain measures are recited in mutually different dependent claims does not indicate that a combination of these measured cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

1. An audio-processing device comprising:
an audio input, for receiving one or more audio signals detected at respective microphones, each of the audio signals comprising a mixture of a plurality of components, each component corresponding to a sound source;
a control input, for receiving, for each sound source, a desired gain factor associated with the source, by which it is desired to amplify the corresponding component;
an auxiliary signal generator, adapted to generate at least one auxiliary signal from the one or more audio signals, the at least one auxiliary signal comprising a different mixture of the components as compared with a reference one of the one or more audio signals, wherein the levels of the components in the at least one auxiliary signal are related to their respective levels in the reference audio signal by known reweighting factors;
a scaling coefficient calculator, adapted to calculate a set of scaling coefficients in dependence upon the desired gain factors and upon the reweighting factors, each scaling coefficient associated with one of the at least one auxiliary signal and optionally the reference audio signal; and
an audio synthesis unit, adapted to synthesize an output audio signal by applying the scaling coefficients to the at least one auxiliary signal and optionally the reference audio signal and to combine the results,
wherein the scaling coefficients are calculated from the desired gain factors and the reweighting factors such that the synthesized output signal provides the desired gain factor for each component.

2. A handheld personal electronic device comprising
a plurality of microphones; and
the audio processing device of claim 1.

3. The mobile or handheld device of claim 2, wherein the microphones are omni-directional microphones.

4. A method of processing audio signals comprising:
receiving one or more audio signals detected at respective microphones, each of the audio signals comprising a mixture of a plurality of components, each component corresponding to a sound source;
receiving, for each sound source, a desired gain factor associated with the source, by which it is desired to amplify the corresponding component;
generating at least one auxiliary signal from the one or more audio signals, the at least one auxiliary signal comprising a different mixture of the components as compared with a reference one of the one or more audio signals, wherein the levels of the components in the at least one auxiliary signal are related to their respective levels in the reference audio signal by known reweighting factors;
calculating a set of scaling coefficients in dependence upon the desired gain factors and upon the reweighting factors, each scaling coefficient associated with one of the at least one auxiliary signal and optionally the reference audio signal; and
synthesizing an output audio signal by applying the scaling coefficients to the at least one auxiliary signal and optionally the reference audio signal and combining the results,
wherein the scaling coefficients are calculated from the desired gain factors and the reweighting factors such that the synthesized output signal provides the desired gain factor for each component.

5. The method of claim 4, wherein:
the desired gain factors; the reweighting factors and the scaling coefficients are related by a linear system equations; and
the step of calculating the set of scaling coefficients comprises solving the system of equations.

6. The method of claim 4, wherein the at least one auxiliary signal is a linear combination of any of:
one or more of the audio signals;
one or more temporally shifted versions of the audio signals; and
one or more filtered versions of the audio signals.

7. The method of claim 4, wherein the at least one auxiliary signal is generated by at least one of:
fixed beamforming;
adaptive beamforming; and
adaptive spectral modification.

8. The method of any of claim 4, wherein:
a first auxiliary signal is generated by a first method;
a second auxiliary signal is generated by a second, different method; and
the second auxiliary signal is generated based on an output of the first method.

9. The method of any of claim 4, comprising:
synthesizing a first output audio signal by applying scaling coefficients to a first reference audio signal and at least one first auxiliary signal and combining the results; and
synthesizing a second output audio signal by applying scaling coefficients to a second, different reference audio signal and at least one second auxiliary signal and combining the results.

10. The method of claim 4, wherein the sound sources comprise one or more localised sound sources and a diffuse noise field.

11. The method of claim 4, wherein the desired gain factors are time-varying.

12. The method of any of claim 4,
wherein the desired gain factors are chosen in dependence upon the state of a visual zoom function.

13. A computer program comprising computer program code means adapted to perform all the steps of any of claim 4 when said program is run on a computer.

14. A computer program as claimed in claim 13 embodied on a computer readable medium.
